(19) United States
(12) Patent Application Publication
(10) Pub. No.: US 2007/0209932 A1
(43) Pub. Date: Sep. 13, 2007

(54) Sputter deposition system and methods of use

(75) Inventors: Piero Sferlazzo, Marblehead, MA (US); Ming Mao, Pleasanton, CA (US); Jinliang Chen, Fremont, CA (US); David Felsenthal, Marblehead, MA (US); Robert Gabriel Hieronymi, Monroe, NY (US); Miroslav Eror, Old Tapan, NJ (US)

Correspondence Address: WOOD, HERRON & EVANS, LLP, 2700 CAREW TOWER, 441 VINE STREET, CINCINNATI, OH, 45202, US

(73) Assignee: Veeco Instruments Inc., Woodbury, NY (US)

(21) Appl. No.: 11/372,517

(22) Filed: Mar. 10, 2006

(51) Int. Cl. C23C 14/00

(52) U.S. Cl. 204/298.16

(57) ABSTRACT

The present invention relates to a sputter deposition system and to methods of use thereof for processing substrates using planetary sputter deposition methods. The sputter deposition system includes a deposition chamber having an azimuthal axis. A rotatable member is situated in the chamber and includes a plurality of magnetrons provided thereon. Each magnetron includes a corresponding one of a plurality of sputtering targets. The rotatable member is configured to position each of the magnetrons to direct sputtered material from the corresponding one of the sputtering targets to a deposition zone defined in the deposition chamber. A transport mechanism is situated in the deposition chamber and includes an arm rotatable about the azimuthal axis. A substrate holder is attached to the arm of the transport mechanism and supports the substrate as the arm rotates the substrate holder to intersect the deposition zone for depositing sputtered material on the substrate.

### FIELD OF THE INVENTION

The present invention relates to a sputter deposition system that contains at least one rotatable member having a plurality of magnetrons mounted thereon, each magnetron including a corresponding sputter target, and to methods of use thereof for processing substrates, like wafers for semiconductor devices and data storage components, using planetary sputter deposition methods for depositing sputtered material on such substrates.

### BACKGROUND OF THE INVENTION

Physical vapor deposition (PVD) modules or systems are used in the manufacture of sensor elements, for example, for spin-valve giant magnetoresistance (GMR) and tunneling magnetoresistance (TMR) read/write heads for the data storage industry and similar devices. With PVD, typically thin layers or films of magnetic and non-magnetic materials are stacked on a substrate using a sputtering system, which includes a vacuum chamber having one or multiple cathodes with one source target mounted on each cathode. During the sputtering process, material is removed from the source target and subsequently deposited on the substrate to form one or more layers of a desired thickness. It is also desirable that the layers formed on the substrate have a highly uniform thickness. By way of example, a high level of thickness uniformity not exceeding 1%3σ or higher may be desirable, such as for heads for magnetic data storage and retrieval.

One class of conventional PVD modules or systems utilizes planetary sputter deposition which relies on motion providing both an arc shaped movement, i.e. sun rotation, in conjunction with simultaneous spinning, i.e. planet rotation, of the substrate. This compound pattern of movement, or planetary motion, generally provides a desirable thickness uniformity. By way of example, to deposit an alloy on a substrate using planetary sputter deposition, a single alloyed sputter source of a desired composition may be situated about the periphery of the top or bottom of a cylindrical vacuum chamber. The substrate is placed on a substrate holder that constitutes part of an assembly with a rotary arm. The substrate holder, which is at the end of the rotary arm, generally incorporates provisions to continuously rotate the substrate at relatively high speed during a deposition cycle. The radius of rotation is such that the center of the substrate is approximately aligned with the center of the sputter source to achieve the specified film parameters. As the substrate passes or loops by the alloyed sputter source, a layer of material defining the alloy is sputter deposited on the substrate. Multiple passes may be performed to obtain stacked layers of desired thickness. Multi-layers consisting of component layers with different materials can be deposited by using multiple sputter sources spaced about the vacuum chamber.

The length of the sputter sources with planetary sputter deposition is usually 1.5 to 2.0 times the substrate diameter to assure good intrinsic thickness uniformity for the film deposited on the substrate. The required characteristics of the deposited film (e.g., uniformity and thickness control) are achieved by the control of the scanning motion of the spinning substrate under the sputter source.

Feature size reductions along with a desire to reduce overall production costs in the data storage and semiconductor industries has created a movement to improve sputter deposition systems and methods of sputter depositing material on substrates while maintaining or improving control over the thickness and/or uniformity of the sputtered material on the substrate surface.

Accordingly, to increase process throughput and, thus, reduce manufacturing costs, e.g., of microelectronic devices, it is desirable to be able to deposit multiple layers of magnetic and non-magnetic materials on a substrate(s) without removing the substrate from a process chamber. Certain sputtering systems, however, are designed to deposit only one material on a substrate, which material may be a single metal or alloy thereof, a dielectric, or a combination of several metals or dielectrics. Thus, if multiple layers of different materials are to be deposited on a substrate, these sputtering systems need to be reconfigured and the substrate has to be cycled from atmosphere to vacuum, which can result in the formation of undesirable interface layers. In other sputtering systems, multiple layers of metals or dielectric films are sequentially deposited in different process chambers. Moving the substrates from one process chamber to another process chamber typically causes a change in vacuum base pressure and in the temperature of the substrate. These pressure and temperature changes also may result in the formation of undesirable interface layers in the multilayer film.

In other sputtering systems, a number of sputter sources are integrated in one process chamber. However, the number of the target materials is not enough to complete the desired multilayer stack on a substrate and, therefore, more chambers are still required. In other instances, the number of target materials is sufficient but the distribution of the plurality of sputter sources within the process chamber requires too large a chamber size. In both of these cases, the sputtering system footprint is unacceptable for mass production.

Additionally, it is desirable to reduce the frequency in which worn sputter targets are changed out in a deposition system. With certain deposition systems, only a single target of a desired material is provided for sputtering thereof in a process chamber. As such, after the target is worn, production must be stopped so that the worn target can be removed and replaced by a new target since there is no backup target of the same material contained within the process chamber. Consequently, process throughput is slowed, thus, increasing manufacturing costs.

What is needed, therefore, is an improved sputter deposition system and a method for sputter depositing layers of magnetic and non-magnetic materials on a substrate that addresses the above drawbacks of sputter deposition systems so that process throughput may be increased, thus, reducing manufacturing costs.

### SUMMARY OF THE INVENTION

In accordance with an embodiment of the invention, a sputter deposition system for depositing at least one layer on a substrate includes a deposition chamber having an azimuthal axis and at least one rotatable member associated with the deposition chamber. The rotatable member includes a plurality of magnetrons provided thereon with each of the plurality of magnetrons including a corresponding one of a plurality of sputtering targets. The rotatable member is configured to position each of the magnetrons to direct sputtered material from the corresponding one of the sputtering targets to a deposition zone defined in the deposition chamber.

A transport mechanism is situated within the deposition chamber and further includes an arm rotatable about the azimuthal axis. A substrate holder is attached to the arm of the transport mechanism at a first radius from the azimuthal axis. The substrate holder supports the substrate as the arm rotates the substrate holder about the azimuthal axis to intersect the deposition zone(s) for depositing sputtered material on the substrate. The substrate holder may be configured to rotate about a central rotation axis for rotating the substrate as the arm transports the substrate through the deposition zone. In addition, a processor may be provided in communication with the transport mechanism, wherein the processor instructs the transport mechanism to rotate the arm about the azimuthal axis through the deposition zone at first and second angular velocities. The different velocities provide for a substantially uniform thickness of the sputtered material on the substrate.

Each of the plurality of targets of the present invention can include one or more magnetic and non-magnetic materials of metallic or semi-conductive nature. These materials may be chosen from the elements of Groups 1-15 of the periodic table. The targets are selected based upon the material desired on the substrate. One or more targets may be composed of more than one magnetic and non-magnetic material.

In accordance with a method of the present invention, at least one rotatable member of the deposition system can rotate a sputter target of a first magnetron, which is supported by the rotatable member, to proximate a deposition zone defined in the deposition chamber for directing sputtered material from the target to the deposition zone. A substrate is provided on the substrate holder and rotated by the rotary arm about the azimuthal axis through the deposition zone during sputter deposition for depositing sputtered material on the substrate. During rotation, the trajectory of the center of the substrate passes by the center of the target.

As the substrate moves once around the chamber, i.e. performs one pass or loop by the target, the target sputters on the substrate to deposit a layer of sputtered material. This process may be repeated until a desired number of layers or a desired thickness is obtained. In addition, after a single pass, the rotatable member may be rotated to select another sputtering target associated with a second magnetron, such as for providing one or more different sputtered materials on the substrate. Also, more than one rotatable member may be provided in the deposition chamber, such as to provide multiple layers of sputtered material on the substrate during a single pass.

The deposited thickness of each layer sputtered on the substrate may be controlled, using planetary sputter deposition techniques, by adjusting the substrate sweeping velocity at fixed target power or vice versa, i.e. by adjusting the target power at fixed substrate sweeping velocity. The thickness uniformity of the layers is maintained by velocity profiling and by rotation of the substrate. As such, the substrate may be transported by the rotary arm about the azimuthal axis through the deposition zone at first and second angular velocities to provide a substantially uniform thickness of the material on the substrate.

The sputter deposition system of the present invention, accordingly, is compact, i.e. provides a small footprint, and can deposit multiple layers of different magnetic and non-magnetic materials on a substrate(s) without removing the substrate from the deposition chamber and further can reduce the frequency in which worn sputter targets are changed out, thereby increasing process throughput and, thus, reducing manufacturing costs. As such, the sputter deposition system, and methods of use thereof, overcomes the performance limitations and associated cost disadvantages of other sputter deposition systems.

These and other objects and advantages of the present invention shall become more apparent from the accompanying drawings and description thereof.

### BRIEF DESCRIPTION OF THE DRAWINGS

The accompanying drawings, which are incorporated in and constitute a part of this specification, illustrate embodiments of the invention and, together with a general description of the invention given above, and the detailed description of the embodiments given below, serve to explain the principles of the invention.

FIG. 1 is a perspective view of the exterior of a sputter deposition system in accordance with the present invention;

FIG. 2 is a schematic plan view of the interior of the sputter deposition system of FIG. 1 illustrating a method of use thereof in accordance with the present invention;

FIG. 3 is a schematic elevational view of the rotatable member with source target and transport mechanism with substrate of FIG. 2 further illustrating the method of use in accordance with the present invention;

FIG. 4 is an exploded perspective view of a rotatable member of the sputter deposition system of FIG. 1; and

FIG. 5 is a schematic plan view of the sputter deposition system of FIG. 2 illustrating specific parameters of the system useful for optimizing film thickness uniformity by velocity profiling in accordance with the present invention.

### DETAILED DESCRIPTION OF SPECIFIC EMBODIMENTS

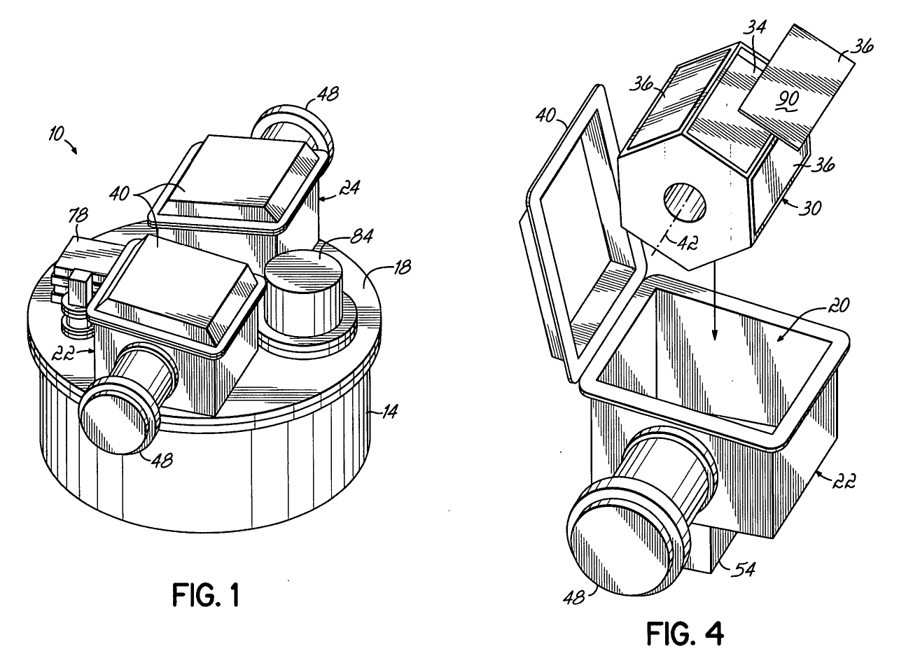

FIGS. 1-5 illustrate a sputter deposition system 10 in accordance with the present invention for depositing at least one layer of magnetic or non-magnetic material on a substrate 12 using planetary sputter deposition techniques. Although further discussed below, U.S. Pat. No. 5,795,448 describes the general operation of a planetary process module or device and is hereby incorporated by reference herein in its entirety.

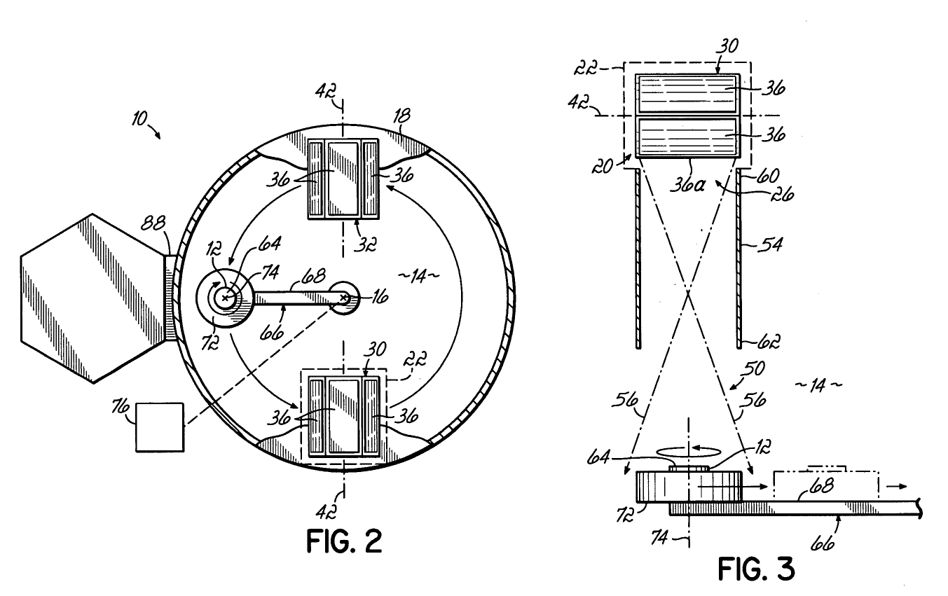

As best shown in FIGS. 1 and 2, the sputter deposition system 10 of the present invention includes a deposition chamber 14 having an azimuthal axis 16 and a chamber lid 18. Two containers 22 and 24 are situated on the chamber lid 18 with the interior 20 of each container 22, 24 being in communication, or association, with the deposition chamber 14 via corresponding openings 26 (only one shown—See FIG. 3) in the chamber lid 18. The deposition chamber 14, including the interior 20 of the containers 22, 24, defines an evacuable or controlled atmosphere volume. Each container 22, 24 further includes, respectively, rotatable member 30 and 32 rotatably mounted therein with each rotatable member 30, 32, accordingly, being in communication, or association, with the deposition chamber 14 via the openings 26. U.S. Pat. No. 6,328,858, which is hereby incorporated by reference herein in its entirety, describes a suitable type of rotatable member for use with the present invention.

As best shown in FIGS. 2 and 4, the rotatable members 30, 32 further include a plurality of magnetrons 34 (only one shown—See FIG. 4), e.g. linear magnetrons, removably supported thereon. Each of the plurality of magnetrons 34 has a corresponding one of a plurality of sputtering targets 36 similarly removably supported thereon. The containers 22, 24 also include a lid 40 that may be moved between an open and closed position to provide access to the rotatable members 30, 32, for example, so that the magnetrons 34 and targets 36 may be removed and replaced, such as when worn or in need of repair. The rotatable members 30, 32 are adapted to rotate about central axes 42 and, more specifically, each of the rotatable members 30, 32 may be rotated about their central axis 42 by a motor 48, such as a direct or belt drive motor.

The rotatable members 30, 32 are hexagonal in shape with each member 30, 32 including six magnetrons 34 and six corresponding targets 36. It should be understood, however, that the rotatable members 30, 32 may be designed to accommodate less than or more than six magnetrons 34 including their associated sputter targets 36. It should be further understood that only one or more than two rotatable members may be provided with the system 10. As further explained below, the rotatable members 30, 32 can be rotated to position a desired magnetron 34 to direct sputtered material from the corresponding one of the sputtering targets 36 through the opening 26 to a deposition zone 50 (FIG. 3) defined in the deposition chamber 14. In one example, a processor (not shown) in communication, e.g. electrical communication, with the rotatable members 30, 32 can instruct the rotatable members 30, 32 to position one of the sputtering targets 36 for depositing sputtered material on the substrate 12.

With further reference to FIG. 3, each rotatable member 30, 32 (only one shown—namely, numeral 30) is associated with a chimney 54 for confining sputtered material, as represented by arrows 56. More specifically, chimney 54 includes a proximal end 60 situated about opening 26 and further includes a distal end 62 defining one of the deposition zones 50. The substrate 12 is adapted to sweep by the deposition zones 50 so that the confronting surface 64 of the substrate 12 is exposed to deposition fluxes 56, which accumulate as a layer or film.

As shown in FIGS. 2 and 3, a transport mechanism 66 is situated within the deposition chamber 14 and further includes an arm 68 rotatable about the azimuthal axis 16. A substrate holder 72 is attached to the arm 68 of the transport mechanism 66 at a first radius from the azimuthal axis 16. The substrate holder 72 may be an electrostatic chuck, which is commonly used in the semiconductor industry. The substrate holder 72 may include a magnet (not shown), which may be a permanent magnet or an electromagnet, providing an aligning magnetic field with sufficient field strength with a directional dispersion less than 1.5 degrees to orient the in-plane magnetization of the deposited magnetic films. The substrate holder 72 may also include cooling channels (not shown) for carrying cooling fluid. The cooling fluid, such as water, passes through the cooling channel and removes heat from the substrates 12 being processed.

The substrate holder 72 supports the substrate 12 as the arm 68 rotates the substrate holder 72 about the azimuthal axis 16 to intersect the deposition zones 50 for depositing sputtered material on the substrate 12. The substrate holder 72 also may be configured to rotate about a central rotation axis 74 for rotating the substrate 12 as the arm 68 transports the substrate 12 through the deposition zones 50. Although only one arm 68 is shown, a person of ordinary skill in the art will appreciate that multiple arms similar to arm 68 may be arranged in a hub and spoke arrangement for use in moving multiple substrates 12 through the deposition zones 50. In addition, a processor 76 in communication, e.g. electrical communication, with the transport mechanism 66 can instruct the transport mechanism 66 to rotate the arm 68 about the azimuthal axis 16 through the deposition zones 50 at first and second angular velocities and/or instruct the substrate holder 72 to rotate about the central rotation axis 74 at a desired speed. The different angular velocities, as further explained below, can provide for a substantially uniform thickness of the sputtered material on the substrate 12.

The deposition chamber 14 may be accessed through a substrate load/unload port 88 (FIG. 2) that normally is isolated therefrom. The load/unload port 88 is adapted for introducing substrates 12 to, and removing processed substrates from, the substrate holder 72 within the chamber 14, such as by way of a transfer robot (not shown) or other means known in the art.

With further reference to FIGS. 1 and 2, the sputter deposition system 10 can also include an ion source (e.g. an ion gun), generally represented by numeral 78, that is associated with the deposition chamber 14 and used for ion or ion beam assistance, including cleaning of the substrate 12 prior to depositing sputtered material 56 on the substrate surface 64, film densification, surface smoothing and oxidation. A neutralizer, also generally represented by numeral 78, may be provided together with the ion source 78 and, likewise, is associated with the deposition chamber 14 so as to maintain a neutral atmospheric charge therein, such as during use of the ion source 78. Specifically, the ion source and neutralizer 78 are situated on the chamber lid 18 with each 78 being in communication with the deposition chamber 14 via openings (not shown) in the lid 18. Additionally, a heating lamp or an additional sputter source, which could be one or more RF or DC magnetrons, as generally represented by numeral 84, may be provided on the chamber lid 18, such lamp or sputter source 84 similarly being in communication with the deposition chamber 14 via an opening (not shown) in the lid 18. Heating lamp and sputter source 84, respectively, is used to control the temperature within the chamber 14 or provided for sputtering nonmetallic or dielectric targets, as well as metallic elemental or alloy targets.

Each of the plurality of targets 36 of the present invention can include one or more magnetic materials or non-magnetic materials of metallic or semi-conductive nature. These materials can be chosen from the elements of Groups 1-15 of the periodic table, such as from a transition metal, lithium, beryllium, boron, carbon, and/or bismuth. In one example, the targets 36 include no less than about 99% of magnetic or non-magnetic material chosen from the elements of Groups 1-15 of the periodic table, such as from a transition metal, lithium, beryllium, boron, carbon, and/or bismuth. In another example, each of the plurality of targets 36 includes no less than about 99.9% and, in yet another example, no less than about 99.99% of magnetic or non-magnetic material chosen from Groups 1-15 of the periodic table, such as from a transition metal, lithium, beryllium, boron, carbon, and/or bismuth.

In addition, the atmosphere during sputter deposition of materials may include, for example, oxygen, nitrogen, etc., such as to provide a means to assist layer-by-layer film growth for smooth surface and/or interfaces. The incorporation of pulsed DC power supply with asymmetric negative and positive output potential can allow for sputter formation of thin dielectric films, including oxides and nitrides.

Each of the twelve total targets 36 of rotatable members 30, 32, as depicted in FIGS. 2-4, may include a different material, or combination of materials or alloys, to allow for up to twelve different sputterable materials. In the alternative, two or more targets 36 may be provided with the same material, such as to provide a backup target after one target becomes worn, thereby reducing interruptions in productivity.

As further shown in FIGS. 2 and 3 and in accordance with a method of the present invention, each of the rotatable members 30, 32 of the deposition system 10, can rotate to align one of the plurality of sputtering targets 36a (only one shown—See FIG. 3) with corresponding opening 26 (FIG. 3) for directing sputtered material 56 (FIG. 3) to deposition zone 50 (FIG. 3). Accordingly, the substrate 12 is provided on the substrate holder 72 and rotated by the arm 68 about the azimuthal axis 16 through the deposition zones 50 during sputter deposition for depositing sputtered material 56 on the substrate 12. The center of the substrate 12 is approximately aligned with the center of the selected target 36a when the substrate 12 sweeps by the target 36a.

As the substrate 12 moves once around the chamber 14, i.e. performs one pass or loop by each of the rotatable members 30, 32, each of the selected targets 36a (only one shown) sputter on the substrate 12 to deposit a layer of magnetic or non-magnetic material. This process may be repeated until a desired number of layers and materials are obtained. In exemplary embodiments, the arm 68 rotates the substrate 12 360° about the azimuthal axis 16 by each of the rotatable members 30, 32 for each pass. However, it should be understood by one skilled in the art that multiple passes by rotatable members 30, 32 can be performed without rotating 360° about the azimuthal axis 16 insofar as the arm 68 may stop during rotation and reverse direction in the chamber 14 as many times as is desired. To cause stacking of layers, each layer generally includes a thickness greater than about 6 Å. In addition, the substrate 12 may be transported by the arm 68 about the azimuthal axis 16 through the deposition zones 50 at first and second angular velocities to provide a substantially uniform thickness of the material on the substrate 12. After a single pass, one or both of the rotatable members 30, 32 may be rotated about their axis 42 to select another sputtering target 36 associated with another magnetron 34, such as for providing one or more different sputtered materials on the substrate 12. Also, alloys or combinations of two or more different materials can be prepared if each pass allows a layer to be deposited having a thickness of about an atomic layer so that different materials can intermix at atomic levels, thereby forming homogeneous alloys of desired compositions.

The number of rotatable members 30, 32, as well as the number of targets 36 and choice of sputterable materials, is selected based upon the materials desired on the substrate 12. For example, for sputter depositing a multilayer of cobalt-iron (CoFe) alloy and copper (Cu) on the substrate 12, one could provide two rotatable members 30, 32 with at least one sputter target 36 on one rotatable member 30 including a CoFe alloy and at least one target 36 on the other rotatable member 32 including copper. In this example, the substrate 12 would only need to make one pass by each rotatable member 30, 32 to provide the multilayer of cobalt-iron alloy then copper on the substrate 12. In another example, only one rotatable member 30 could be provided and include at least two separate targets 36 with one target including the CoFe alloy and the other target including copper. In this example, the substrate 12 would have to make two passes by the rotatable member 30 to apply the CoFe alloy then Cu multilayer with the rotatable member 30 being rotated from the CoFe target to the Cu target after the first pass in order to sputter the copper material onto the CoFe layer during the second pass.

In accordance with this method, the substrate 12 may be provided with a seed layer, as is known in the art, to provide a foundation to firmly adhere an additional layer(s) to the substrate 12 and provide a material microstructure base to enhance the microstructure texture. This seed layer may be sputtered on the substrate 12 within the chamber 14 prior to sputtering of the first target source or it may already be provided on the substrate 12 prior to entering the deposition chamber 14. In addition, a capping layer, as is known in the art, typically is sputtered on the substrate 12 after sputtering of all desired targets on the seed layer. As is understood in the art, the capping layer provides a protective covering for the sputtered layer(s), for example, such as from corrosion due to prolonged exposure to the atmosphere. Each of the targets used to provide the seed and capping layers also may be composed of one or more magnetic and non-magnetic materials. The number of targets and choice of material(s), similarly may be chosen based upon the desired materials for the seed and capping layers.

As indicated above, a control system (not shown) orchestrates the operation of the deposition system 10. More specifically, the speed of the rotational (or planetary motion) and the angular velocity (or sun rotation) of the substrate holder 72, and the deposition from the source targets 36 are controlled by the control system, which has a construction understood by persons of ordinary skill in the art.

With planetary sputter deposition, the substrate 12 typically spins at about 30 to about 1200 rpm about the central rotation axis 74 while rotating at about 0.1 to about 30 rpm about the azimuthal axis 16 as the substrate 12 sweeps by the individual targets 36. However, it should be understood that the planet and sun rotational speeds, respectively, may be less than about 30 rpm and or greater than about 1200 rpm and less than about 0.1 rpm and greater than about 30 rpm. The deposited thickness at any point on the substrate 12 depends on its dwell time beneath the source target 36 and also on its trajectory thereby. Due to the non-uniform nature of the spatial distribution of a sputtered species, approximately in Gaussian form, substrate rotation about the central rotation axis 74 at a constant velocity is not sufficient for a uniform deposition. Therefore, a modulation on the substrate rotation about the azimuthal axis 16 is required, and more specifically, the rotation velocity needs to be profiled so that the integral of the sputtered flux 56 over the trajectory of each point on the substrate 12 will be almost the same to ensure a uniform film thickness distribution across the substrate 12.

For a normalized film or layer thickness contour map on a substrate of any size for depositions in sputter deposition systems using a constant velocity, the film typically is thicker at the center of the substrate and becomes thinner with increasing radial distance. This is consistent with the perception that the substrate edge spends more time in an outer portion of the target where the sputter flux is relatively low. Consequently, a velocity profile, such as 2-step symmetrical profile, may be utilized wherein the substrate 12 is adjusted to travel slower when it first enters the deposition zone 50 to allow for longer dwell time for more deposition, and then speeds up to a desired or normal velocity which defines the desired thickness of deposited material. With a 2-step symmetrical profile, the typical velocity ratio between the desired or maximum velocity and the initial, or slower, velocity is within a factor of 2. For example, if the initial velocity is 5 rpm then the maximum velocity is 10 rpm. The transition between the two velocities can be either stepwise or gradual.

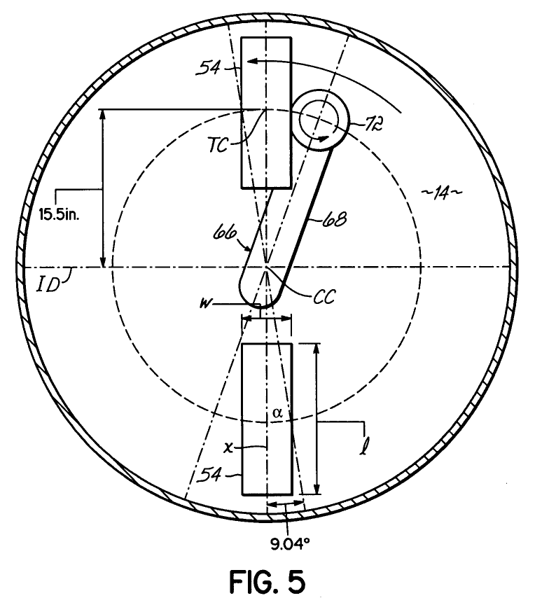

With reference to FIG. 5, to optimize a velocity profile, certain characteristic dimensions of the deposition chamber 14 need to be known including the inner diameter (ID) of the chamber 14 and distance from the chamber center (CC) to the target center (TC). As an example, the ID of the deposition chamber 14 and CC to TC distances, respectively, are depicted as being 50 inches and 15.5 inches. Also, target chimney length (l) and width (w) need to be known and, respectively, are 15 inches and 5.5 inches. From these dimensions, the half angle (α) of the chimney that extends to the chamber center is determined, which in this case is depicted to be about 9°. This half angle determination sets an angular limit for the deposition zones 50 (FIG. 3). Typically, for a 2-step velocity profile, to prevent exposure to the sputter flux 56 (FIG. 3) prior to the deposition, the substrate 12 needs to be positioned, or offset, outside the deposition zone 50 generally greater than about 10° or less than about minus 10° with reference to the target centerline (x). An optimization of the film thickness uniformity is, therefore, a process of adjusting the velocity ratio to balance the exposure or dwell time of different portions along the radius of the substrate 12. Depending upon the requirement, up to 5 steps of the velocity profile can be employed.

The thickness uniformity then can be evaluated, for example, by x-ray reflectivity or fluorescence, ellipsometry, or sheet resistance map of typically 49 to 81 points over the substrate surface. One additional feature that needs to be noticed is the evolution of the thickness profile, which changes from convex shapes with thicker film to concave shapes with thinner film at the center.

After optimization of the deposition uniformity, the deposition rate can be calibrated. Typically, two to three offset rotational velocity values are selected, for example, 0.5, 1, and 2 rpm, at a fixed change of rotational velocity value. A linear regression of the measured thickness in Å/sweep, typically 10-20 sweeps used for rate calibration depositions to achieve a comfortable level of thickness determination, versus 1/offset rotational velocity can be used to determine the deposition rate from which the required offset value for specified layer thickness can be determined. With increasing target erosion, optimization and rate recalibration may be required to ensure the best performance.

Accordingly, the deposited thickness of each layer of magnetic or non-magnetic material in this method may be controlled by adjusting the substrate sweeping velocity at fixed target power, thus, allowing for the layers to be uniform. It should also be understood that the thickness uniformity may also be controlled by adjusting the target power at fixed substrate sweeping velocity. The thickness of each layer may be controlled down to a fraction of an atomic layer such that conventional stacking of layers may be avoided, if desired. The thickness uniformity of the layers is maintained by velocity profiling and by rotation of the substrate 12, as explained above. In one example, uniform thickness deviation of the sputter deposited material is from no greater than about 0.6%3σ over 138 mm measurement diameter.

A non-limiting example in accordance with the method of the present invention is hereby presented for sputter depositing a multilayer composed of magnetic and non-magnetic materials on substrate 12, such as for use as a spin valve. With reference generally to FIGS. 2 and 3, substrate 12 is loaded on substrate holder 72 at the load/unload port 88. The substrate 12 may be composed of any material suitable for the purpose(s) of the coated substrate. In this example, the substrate 12 is a silicon wafer and is 6 inches in diameter. It should be understood that the substrate may be smaller or larger and/or of a different shape.

Within the chamber 14, the substrate 12 is rotated at a desired speed about the central rotation axis 74, such as at about 1200 rpm, with the arm 68 being rotated about the azimuthal axis 16 at specified or optimized angular velocities, as discussed above, to rotate the substrate 12 therearound within the deposition chamber 14. For example the first angular velocity, i.e. initial velocity, may be about 10 rpm until the substrate reaches the offset of about 10° with reference to the target centerline (x) (FIG. 5). After which point, the arm 68 speeds up to its second angular velocity, i.e. a maximum velocity, of about 20 rpm as it moves through the remainder of deposition zone 50. Then, when the substrate 12 reaches the offset of about −10° with reference to the target centerline (x), the arm 68 slows back down to about 10 rpm. This scenario may be repeated at each deposition zone 50.

Rotatable member 30 includes source targets 36 of cobalt-iron (CoFe), and either tantalum (Ta) or nickel-iron-chromium (NiFeCr) and the second rotatable member 32 includes source targets 36 of either platinum-manganese (PtMn) or iridium-manganese (IrMn), and of ruthenium (Ru), copper (Cu), and nickel-iron (NiFe) for forming multiple layers, or spin-valves, on the substrate 12 by way of multiple passes of substrate 12 by desired targets 32, 36. The additional remaining targets 36 of the twelve total targets 36 can include one or more various magnetic and non-magnetic materials, such as different CoFe or cobalt-iron-boron (CoFeB) alloys for stack performance enhancement, and/or aluminum (Al), magnesium (Mg), titanium (Ti) and hafnium (Hf) as tunnel barrier layers for tunnel magnetoresistive devices. The rotatable members 30, 32 are arranged about the azimuthal axis 16 and the center of the substrate 12 is approximately aligned with the center of each target 36 when the substrate 12 sweeps by the deposition zone 50 thereof.

As is generally understood in the art, each magnetron 34 (FIG. 4), which is positioned behind each source target 36, provides a magnetic field at the front target surface 90 (FIG. 4) of the sputtering target 36. As best illustrated in FIG. 3, sputtering target 36a is connected to an electrical power supply (not shown) which, when energized, generates an electric field. The deposition chamber 14 is evacuated and then filled at a low pressure, typically 0.1 to 10 mTorr, with a suitable inert gas, such as argon, krypton or xenon. The electric field generates a plasma discharge in the inert gas adjacent to the sputtering target 36a. The magnetron 34 supplies a magnetic field that confines and shapes the resulting plasma near the front target surface 90 (FIG. 4). Positively-charged ions from the plasma are accelerated toward the negatively-biased sputtering target where the ions bombard the front target surface 90 with sufficient energy to sputter atoms of the target material. The flux 56 of sputtered target material travels ballistically toward the substrate 12 positioned in opposition to the sputtering target 36a inside the deposition chamber 14.

Accordingly, as the substrate 12 moves once around the chamber 14, i.e. performs one pass or loop by each source target 36 positioned for sputtering, the targets 36 are sputtered, in sequence, at a desired target power (generally a fixed target power from about 50-2000 watts), to deposit a layer of a desired thickness of each of the materials on the substrate 12. The seed layer is sputter deposited on the substrate 12 first and includes a sputter deposited layer of either Ta or NiFeCr, or a combination of different materials. Next, the rotatable members 30, 32 including the CoFe, IrMn, Ru, Cu and NiFe targets, are rotated as needed to align with their respective openings 26 and sputtered in defined sequence on the substrate 12, i.e. on the seed layer, as the substrate 12 makes multiple passes for forming a spin-valve stack on the substrate 12. The number of the layers and the thickness of the multi-layers generally is dependent upon the use of the coated substrate.

After the desired number of layers having the desired thickness has been deposited, a capping layer may be sputter deposited on the substrate 12, i.e. on the last layer, in accordance with the process discussed above. The coated substrate then may be removed from the deposition chamber 14 at the load/unload port 88.

The deposited thickness of each layer sputtered on the substrate 12 may be controlled, using planetary sputter deposition techniques, by adjusting the substrate sweeping velocity at fixed target power. The thickness uniformity of the layers is maintained by velocity profiling and by rotation of the substrate 12 about the azimuthal axis 16. The thickness of the material, including the percent composition of each magnetic or non-magnetic material, generally is dependent upon the use of the coated substrate.

The sputter deposition system 10 of the present invention is able to deposit multiple layers of magnetic and non-magnetic materials on a substrate(s) 12 without removing the substrate 12 from the deposition chamber 14 and further can reduce the frequency in which worn sputter targets are changed out to increase process throughput and, thus, reduce manufacturing costs. Accordingly, the sputter deposition system 10, and methods of use thereof, overcomes the performance limitations and cost disadvantages of other known sputter deposition systems.

While the present invention has been illustrated by a description of various embodiments and while these embodiments have been described in considerable detail, it is not the intention of the applicant to restrict or in any way limit the scope of the appended claims to such detail. Additional advantages and modifications will readily appear to those skilled in the art. Thus, the invention in its broader aspects is therefore not limited to the specific details, representative apparatus and method, and illustrative examples shown and described. Accordingly, departures may be made from such details without departing from the spirit or scope of applicant's general inventive concept.

What is claimed is:

1. A sputter deposition system for depositing at least one layer on a substrate, comprising:
a) a deposition chamber having an azimuthal axis;
b) a rotatable member associated with the deposition chamber and including a plurality of magnetrons provided thereon, each of the plurality of magnetrons including a corresponding one of a plurality of sputtering targets, the rotatable member configured to position each of the magnetrons to direct sputtered material from the corresponding one of the sputtering targets to a deposition zone defined in the deposition chamber;
c) a transport mechanism in the deposition chamber, the transport mechanism having an arm rotatable about the azimuthal axis; and
d) a substrate holder attached to the arm of the transport mechanism at a first radius from the azimuthal axis, the substrate holder supporting the substrate as the arm rotates the substrate holder to intersect the deposition zone for depositing sputtered material on the substrate.

2. The deposition system of claim 1 wherein the substrate holder is configured to rotate about a central rotation axis for rotating the substrate as the arm moves the substrate through the deposition zone.

3. The deposition system of claim 1 further comprising:
a processor in communication with the transport mechanism, wherein the processor instructs the transport mechanism to rotate the arm about the azimuthal axis through the deposition zone at first and second angular velocities to provide a substantially uniform thickness of the sputtered material on the substrate.

4. The deposition system of claim 1 further comprising:
a second transport mechanism having an arm that rotates about the azimuthal axis to transport a second substrate through the deposition zone; and
a second substrate holder attached to the arm of the second transport mechanism at a second radius from the azimuthal axis for supporting the second substrate.

5. The deposition system of claim 1 wherein at least one of the sputtering targets comprises at least two materials.

6. The deposition system of claim 1 wherein the rotatable member includes a second rotatable member, each member of the second rotatable member including a plurality of magnetrons provided thereon, each of the plurality of magnetrons of the second rotatable member including a corresponding one of a plurality of sputtering targets, the second rotatable member configured to position each of the magnetrons to direct sputtered material from the corresponding one of the sputtering targets to a second deposition zone defined in the deposition chamber.

7. The deposition system of claim 1 wherein the plurality of magnetrons includes six magnetrons.

8. The deposition system of claim 1 further comprising:
a processor in communication with the rotatable member, wherein the processor instructs the rotatable member to rotate the sputtering target of each of the plurality of magnetrons to align with the deposition zone for depositing sputtered material on the substrate.

9. The deposition system of claim 1 further comprising:
a processor in communication with the transport mechanism, wherein the processor instructs the transport mechanism to transport the substrate through the deposition zone.

10. The deposition system of claim 1 further comprising:
a chimney situated within the deposition chamber and being in association with the rotatable member for confining and directing sputtered material from the corresponding one of the sputtering targets to the deposition zone defined in the deposition chamber.

11. A sputter deposition system for depositing at least one layer on a substrate, comprising:
a) a deposition chamber having an azimuthal axis;
b) a rotatable member associated with the deposition chamber and including a plurality of magnetrons provided thereon, each of the plurality of magnetrons including a corresponding one of a plurality of sputtering targets, the rotatable member configured to position each of the magnetrons to direct sputtered material from the corresponding one of the sputtering targets to a deposition zone defined in the deposition chamber;
c) a transport mechanism in the deposition chamber, the transport mechanism having an arm rotatable about the azimuthal axis;
d) a substrate holder attached to the arm of the transport mechanism at a first radius from the azimuthal axis, the substrate holder supporting the substrate as the arm rotates the substrate holder to intersect the deposition zone for depositing sputtered material on the substrate, the substrate holder further configured to rotate about a central rotation axis for rotating the substrate as the arm moves the substrate through the deposition zone; and
e) a processor in communication with the transport mechanism, wherein the processor instructs the transport mechanism to rotate the arm about the azimuthal axis through the deposition zone at first and second angular velocities to provide a substantially uniform thickness of the sputtered material on the substrate.

12. The deposition system of claim 11 further comprising:
a second transport mechanism having an arm that rotates about the azimuthal axis to transport a second substrate through the deposition zone; and
a second substrate holder attached to the arm of the second transport mechanism at a second radius from the azimuthal axis for supporting the second substrate.

13. The deposition system of claim 11 wherein at least one of the sputtering targets comprises at least two materials.

14. The deposition system of claim 11 wherein the rotatable member includes a second rotatable member, each member of the second rotatable member including a plurality of magnetrons provided thereon, each of the plurality of magnetrons of the second rotatable member including a corresponding one of a plurality of sputtering targets, the second rotatable member configured to position each of the magnetrons to direct sputtered material from the corresponding one of the sputtering targets to a second deposition zone defined in the deposition chamber.

15. The deposition system of claim 11 wherein the plurality of magnetrons includes six magnetrons.

16. The deposition system of claim 11 further comprising:
a chimney situated within the deposition chamber and being in association with the rotatable member for confining and directing sputtered material from the corresponding one of the sputtering targets to the deposition zone defined in the deposition chamber.

17. A method of sputter depositing at least one layer onto a substrate, the method comprising:
a) rotating a rotatable member supporting a plurality of magnetrons to select a sputtering target of a first magnetron;
b) directing material from the sputtering target of the first magnetron to a deposition zone defined in a deposition chamber; and
c) rotating a substrate about an azimuthal axis through the deposition zone.

18. The method of claim 17 further comprising:
rotating the substrate about a central rotation axis perpendicular to the substrate surface as the substrate is transported through the deposition zone.

19. The method of claim 17 further comprising:
rotating the substrate about the azimuthal axis through the deposition zone at first and second angular velocities to provide a substantially uniform thickness of the material on the substrate.

20. The method of claim 17 further comprising:
rotating a second substrate about the azimuthal axis through the deposition zone.

21. The method of claim 17 further comprising:
rotating the rotatable member supporting the plurality of magnetrons to select a sputtering target of a second magnetron,
directing material from the sputtering target of the second magnetron to the deposition zone defined in the deposition chamber, and
rotating the substrate about the azimuthal axis through the deposition zone.

22. The method of claim 17 further comprising:
rotating a second rotatable member supporting a plurality of magnetrons to select a sputtering target of a first magnetron,
directing a first material from the sputtering target of the first magnetron of the second rotatable member to a second deposition zone defined in the deposition chamber; and
rotating the substrate about the azimuthal axis through the second deposition zone.
